(19) United States
(12) Patent Application Publication
(10) Pub. No.: US 2026/0369971 A1
(43) Pub. Date: Nov. 19, 2026

(54) ABOVE-GROUND SWITCHGEAR

(71) Applicant: AMOSENSE CO., LTD., Cheonan-si, Chungcheongnam-do (KR)

(72) Inventors: Jinpyo PARK, Cheonan-si (KR); Hyunwoo JEON, Cheonan-si (KR); Jeonghwan KIM, Cheonan-si (KR)

(73) Assignee: AMOSENSE CO., LTD., Cheonan-si, Chungcheongnam-do (KR)

(21) Appl. No.: 19/148,210

(22) PCT Filed: Jan. 12, 2024
(86) PCT No.: PCT/KR2024/000657

§ 371 Date: Jul. 15, 2025

(30) Foreign Application Priority Data
Jan. 16, 2023 (KR) 10-2023-0005844

(51) Int. Cl. H02B 1/16; H01B 7/00; H01B 7/02; H01B 7/282; H02B 1/20; H02J 50/00; H02J 50/10

(52) U.S. Cl. CPC H02B 1/16; H01B 7/0009; H01B 7/0225; H01B 7/2825; H02B 1/202; H02J 50/001; H02J 50/10

(57) ABSTRACT

Disclosed is an above-ground switchgear capable of increasing the output efficiency of a power induction device by suppressing dispersion of induced power. The above-ground switchgear includes a connector configured to connect, to the above-ground switchgear, an underground power line emerged above ground from underground, an energy harvester installed on the underground power line connected to the connector, and a neutral wire current suppression component installed on a neutral wire of the underground power line, the neutral wire being connected to ground.

### TECHNICAL FIELD

The present disclosure relates to an above-ground switchgear, and more particularly, to an above-ground switchgear used for system configuration of an underground distribution line.

### BACKGROUND ART

In a typical underground distribution line, a transformer is used as a unit for stepping down the voltage from an extra-high voltage of approximately 22.9 kV, which is supplied from a power plant through a transmission line for supplying electric power to households or various industrial facilities, to a low voltage of about 220/380 V suitable for households or various industrial facilities.

In addition, in a 22.9 kV underground distribution line of Korea Electric Power Corporation, a sulfur hexafluoride (SF₆) gas-insulated load break switch (hereinafter referred to as a switchgear) is installed above ground or underground and is used for branching and isolating lines.

FIG. 1 is a diagram illustrating a configuration of a typical underground distribution line system. The system may include an above-ground transformer 2 that receives an extra-high voltage of 22.9 kV from a power plant (or substation) through a transmission line 1 and steps down the voltage to levels suitable for residential commercial power and industrial facility commercial power, respectively, and an above-ground switchgear 3 that opens and closes an underground distribution line. The residential commercial power stepped down by the above-ground transformer 2 is branched and supplied to a low-voltage consumer 4 through the underground distribution line and the above-ground switchgear 3. The industrial facility commercial power stepped down by the above-ground transformer 2 is branched and supplied to a high-voltage consumer 4 through the underground distribution line and the above-ground switchgear 3. The reference numeral 4 denotes a consumer, which may include both a low-voltage consumer and a high-voltage consumer.

The above-ground switchgear is a device used for system configuration of an underground distribution line and for high-voltage power reception. When the underground distribution line system is installed, a neutral wire of a power cable is grounded to an enclosure of the above-ground switchgear for protection of the power cable and for safety purposes.

Here, when electric power is induced from an underground power line (power cable) using a power induction device (e.g., a power current transformer (CT)), an unintended power distribution occurs due to formation of an additional loop other than a core output line of the power induction device. As a result, the amount of power induced by a power harvesting device (i.e., the power induction device) is reduced.

The contents described in the Background Art are to help the understanding of the background of the disclosure, and may include contents that are not a disclosed conventional technology.

### SUMMARY OF INVENTION

### Technical Problem

The present disclosure has been proposed by considering the aforementioned conventional circumstances, and an object of the present disclosure is to provide an above-ground switchgear capable of increasing the output efficiency of a power induction device by suppressing dispersion of induced power.

### Solution to Problem

An above-ground switchgear according to an embodiment of the present disclosure for achieving the aforementioned object may include: a connector configured to connect, to the above-ground switchgear, an underground power line emerged above ground from underground; an energy harvester installed on the underground power line connected to the connector; and a neutral wire current suppression component installed on a neutral wire of the underground power line, the neutral wire being connected to ground.

The neutral wire current suppression component may be an iron-based core.

The neutral wire current suppression component may include: a first core curved in a semi-circular shape and including a first receiving recess formed therein; and a second core curved in a semi-circular shape and including a second receiving recess formed therein. The first core and the second core may be installed to face each other.

The neutral wire current suppression component may be installed to enclose the neutral wire.

The neutral wire current suppression component may increase an impedance of the neutral wire connected to the ground and suppresses current induced through the neutral wire.

According to an embodiment of the present disclosure, the above-ground switchgear may further include a multi-sensor installed on the underground power line emerged above ground, the multi-sensor being installed to be spaced apart from the energy harvester.

The energy harvester may generate power through energy harvesting using a current transformer. The power generated by the energy harvester may be supplied to the multi-sensor.

The underground power line may include a plurality of neutral wires. The plurality of neutral wires may be exposed by a length corresponding to a length with which a sheath of the underground power line connected to the connector is stripped from an upper end of the underground power line downward, and may be bent outward, bundled, and grounded.

The multi-sensor may be installed on an upper portion of the underground power line from which the plurality of neutral wires are exposed and grounded, such that the plurality of neutral wires are not located in the upper portion of the underground power line.

The energy harvester may be installed on a lower portion of the underground power line in which the plurality of neutral wires are present.

According to an embodiment of the present disclosure, the above-ground switchgear may further include a communication board.

The power generated by the energy harvester is supplied to the communication board.

The connector may be grounded.

### Advantageous Effects of Invention

According to the present disclosure having the above-described configuration, a neutral wire current suppression component is installed on a grounded side of a neutral wire of a power cable (i.e., an underground power line) on which a power induction device is installed, thereby increasing impedance of the corresponding line and suppressing the flow of current toward the grounded side.

As a result, current leaking to ground through the neutral wire can be effectively suppressed, thereby preventing dispersion of induced power and further improving the output efficiency of the power induction device.

### BRIEF DESCRIPTION OF DRAWINGS

FIG. 1 is a diagram illustrating a configuration of a typical underground distribution line system.

FIG. 2 is a diagram schematically illustrating a configuration of an above-ground switchgear according to an embodiment of the present disclosure.

FIG. 3 is a view illustrating an example of an internal configuration of a power line cable illustrated in FIG. 2.

FIG. 4 is an enlarged view illustrating a portion of an embodiment of the present disclosure, in which a multi-sensor, a power induction device, and a neutral wire current suppression component are installed.

FIG. 5 is a diagram illustrating the form of a neutral wire bundle illustrated in FIG. 4.

FIG. 6 is an exploded perspective view illustrating the neutral wire current suppression component according to an embodiment of the present disclosure.

FIG. 7 is an enlarged view for explaining an installation position of the neutral wire current suppression component.

FIG. 8 is a cross-sectional view illustrating the neutral wire current suppression component installed on a neutral wire.

FIG. 9 is a diagram for explaining the output efficiency of the power induction device resulting from the neutral wire current suppression component.

### DESCRIPTION OF EMBODIMENTS

The present disclosure may be changed in various ways and may have various embodiments. Specific embodiments are to be illustrated in the drawings and specifically described.

It should be understood that the present disclosure is not intended to be limited to the specific embodiments, but includes all of changes, equivalents and/or substitutions included in the spirit and technical range of the present disclosure.

Terms used in the present application are used to merely describe specific embodiments and are not intended to restrict the present disclosure. An expression of the singular number includes an expression of the plural number unless clearly defined otherwise in the context. In the present application, it is to be understood that a term, such as “include” or “have”, is intended to designate that a characteristic, a number, a step, an operation, a component, a part or a combination of them described in the specification is present, and does not exclude the presence or addition possibility of one or more other characteristics, numbers, steps, operations, components, parts, or combinations of them in advance.

All terms used herein, including technical terms or scientific terms, have the same meanings as those commonly understood by a person having ordinary knowledge in the art to which the present disclosure pertains, unless defined otherwise in the specification. Terms, such as those defined in commonly used dictionaries, should be construed as having the same meanings as those in the context of a related technology, and are not construed as ideal or excessively formal meanings unless explicitly defined otherwise in the specification.

Hereinafter, various embodiments of the present disclosure are more specifically described with reference to the accompanying drawings. In describing the present disclosure, in order to help general understanding, the same reference numerals are used to denote the same components throughout the drawings, and a redundant description of the same components is omitted.

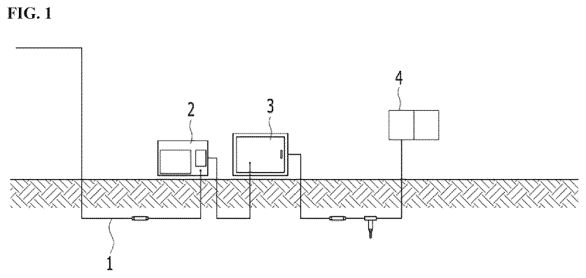

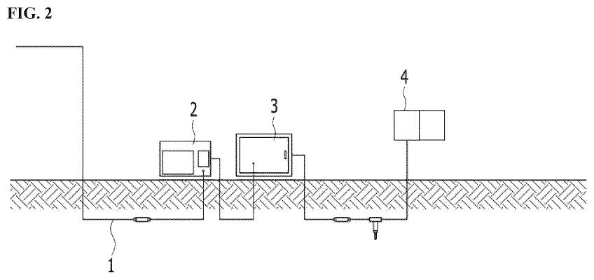

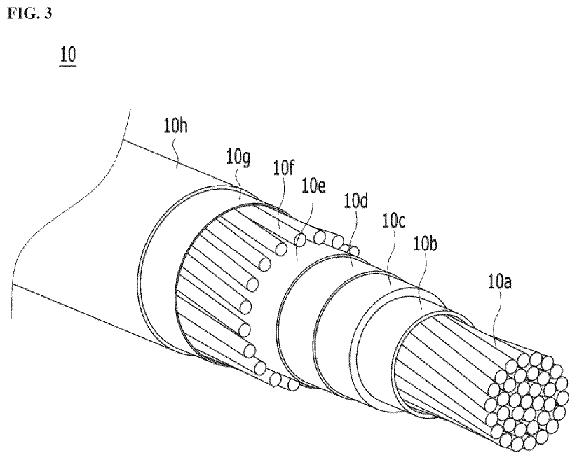

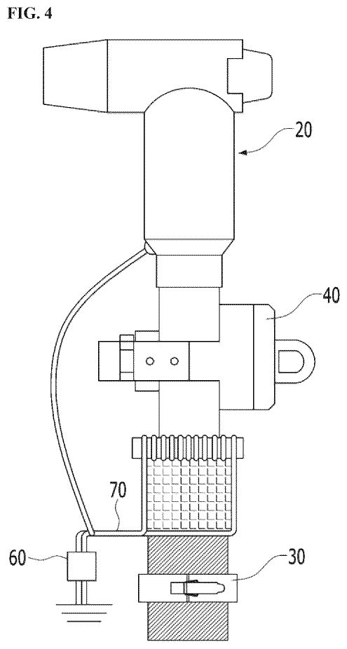

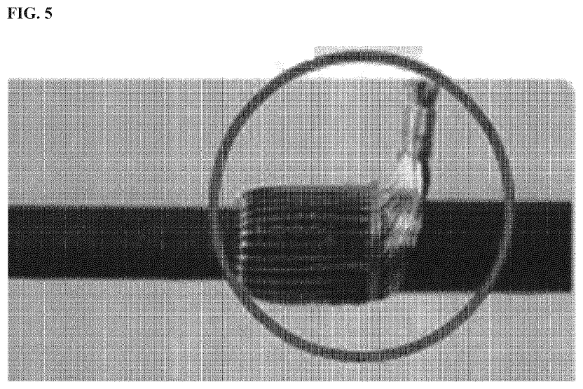

FIG. 1 is a diagram illustrating a configuration of a typical underground distribution line system. FIG. 2 is a diagram schematically illustrating a configuration of an above-ground switchgear according to an embodiment of the present disclosure. FIG. 3 is a view illustrating an example of an internal configuration of a power line cable illustrated in FIG. 2. FIG. 4 is an enlarged view illustrating a portion of an embodiment of the present disclosure, in which a multi-sensor, a power induction device, and a neutral wire current suppression component are installed. FIG. 5 is a diagram illustrating the form of a neutral wire bundle illustrated in FIG. 4.

An above-ground switchgear 100 according to an embodiment of the present disclosure may include a power cable 10, a cable connector 20, a power induction device 30, a multi-sensor 40, and a communication board 50.

The power cable 10 extends from underground to above ground, is connected to the cable connector 20, and is connected to a bushing (not shown) of the above-ground switchgear 100.

As illustrated in FIG. 3, the power cable 10 may include a conductor 10a that functions as a current flow path, an inner semiconductive layer 10b that encloses the conductor 10a and is formed of a semiconductive material (e.g., semiconductive thermosetting compound) to equalize an electric field, an insulating layer 10c that encloses the inner semiconductive layer 10b, withstands voltage, and prevents current from leaking outside the conductor 10a, an outer semiconductive layer 10d that encloses the insulating layer 10c and is formed of a semiconductive material (e.g., semiconductive thermosetting compound) to equalize the electric field, a first neutral wire waterproof layer 10e and a second neutral wire waterproof layer 10g which enclose the outer semiconductive layer 10d and are formed of a black nonwoven fabric that swells upon contact with water to block water penetration and between which a plurality of neutral wires 10f are installed, and a sheath 10h that encloses the second neutral wire waterproof layer 10g.

Here, the neutral wire 10f may function as a current flow path and may be grounded, as illustrated in FIG. 4. In FIG. 4, reference numeral 70 denotes a bundle of neutral wires, and a plurality of neutral wires 10f are bound together by a copper binding wire. For example, in order to secure a predetermined length of the neutral wire 10f, the sheath 10h and the second neutral wire waterproof layer 10g are stripped by a predetermined length. Thereafter, the neutral wires 10f are bent outward so as to be evenly arranged along an outer surface of the sheath 10h, and the neutral wires 10f are gathered together and bound with the copper binding wire. In this manner, the neutral wires may be arranged in the form shown inside the circle in FIG. 5. By connecting the neutral wire bundle 70 having the aforementioned binding structure to an enclosure of the above-ground switchgear 100, grounding of the neutral wires is achieved. Ultimately, it may be regarded that the plurality of neutral wires 10f installed inside the power cable 10 are exposed due to removal of a surface layer of the power cable 10 to a predetermined length and thickness, and the exposed neutral wires 10f are bundled together and connected to the enclosure of the above-ground switchgear 100, thereby being grounded. For example, the plurality of neutral wires 10f may be exposed over a length corresponding to a length by which the surface layer of the power cable 10 is stripped in a downward direction from an upper end of the power cable 10 connected to the cable connector 20, and may be bent outward and bundled to be grounded. Accordingly, as the plurality of neutral wires 10f are exposed and bent outward from the power cable 10, neutral wires are no longer present in an upper portion of the power cable 10, and neutral wires remain in a lower portion of the power cable 10 in which the plurality of neutral wires 10f are not exposed.

As needed, a power cable in which the neutral wires 10f are not grounded may also be provided.

In embodiments of the present disclosure, the power cable 10 may also be referred to as an underground power line or an underground cable.

In FIG. 2, the cable connector 20 is configured to connect two different power cables in series, or to connect a single power cable 10 to an electrical device such as the above-ground switchgear 100.

In an embodiment of the present disclosure, the cable connector 20 is an elbow-type cable connector, and is used to connect a single power cable 10 to an electrical device such as the above-ground switchgear 100, as shown in FIG. 4. The cable connector 20 may be an example of a connector described in the claims of the present disclosure.

The cable connector 20 is grounded through a grounding connector (or a grounding wire).

An end of the cable connector 20 may be electrically connected to the bushing (not shown) of the above-ground switchgear 100, and a remaining end thereof may be electrically connected to the power cable 10 emerged above ground from underground. The internal structure of the cable connector 20 can be easily understood by a person skilled in the art based on well-known techniques.

In FIG. 2, the power induction device 30 may be installed below the installation position of the multi-sensor 40 due to space constraints. As illustrated in FIG. 4, the power induction device 30 may be installed below the power cable 10 coupled to the cable connector 20. Since the multi-sensor 40 is installed above the power cable 10 coupled to the cable connector 20, it is appropriate, in consideration of the available space, for the power induction device 30 to be installed below the power cable 10 coupled to the cable connector 20. In other words, even from FIG. 4, it can be seen that the power induction device 30 is installed to enclose the neutral wires 10f in the power cable 10. For example, the power induction device 30 may be installed at a portion of the power cable 10 where the surface layer thereof is not stripped (that is, at a lower portion of the power cable 10 in which the plurality of neutral wires 10f are present).

The power induction device 30 may be configured to generate electrical energy (i.e., power) using a magnetic field induced in the power cable 10.

For example, the power induction device 30 may collect a leakage magnetic field around the power cable 10 using a high-density induction coil and generate an AC voltage. In this manner, the power induction device 30 may perform self-generation using an energy harvesting technique.

Since the power induction device 30 can perform self-generation using a power current transformer (Power CT), the power induction device 30 may also be referred to as an energy harvester.

The electric energy generated by the power induction device 30 may be used as driving power for the multi-sensor 40 and the communication board 50.

That is, the induced voltage generated in a core of the power induction device 30 due to the electromagnetic wave of the power cable 10 may be an AC voltage. The electric energy (e.g., AC voltage) generated by the power induction device 30 may be converted into a DC voltage by a control box (not shown) and supplied as driving power to the multi-sensor 40 and the communication board 50.

As needed, the power induction device 30 may include a converter configured to convert an AC voltage into a DC voltage.

As the power induction device 30 capable of self-power generation through the energy harvesting technique is used, it is possible to continuously supply power to the multi-sensor 40 and the communication board 50. In particular, the use of the power induction device 30 capable of self-power generation through the energy harvesting technique enables the multi-sensor 40 and the communication board 50 to operate without a separate battery.

It is desirable that the power induction device 30 be waterproofed, so that even when water is drawn into the above-ground switchgear 100 due to rain or the like, there is no problem in generating operating power for the multi-sensor 40 and the communication board 50.

In FIG. 2, the multi-sensor 40 may be installed on an upper portion of the power cable 10 coupled to the cable connector 20. That is, as illustrated in FIG. 4, the multi-sensor 40 may be installed to partially enclose a portion of the power cable 10 where the neutral wires 10f are exposed and stripped. For example, the multi-sensor 40 may be installed on the upper portion of the power cable 10 from which the plurality of neutral wires 10f are exposed and grounded, such that the plurality of neutral wires 10f are no longer present in the upper portion of the power cable 10. As needed, the multi-sensor 40 may also be installed on the cable connector 20.

The multi-sensor 40 may measure, in real time, the current of the power cable 10 and the temperature of the cable connector 20 in the above-ground switchgear 100. As needed, the multi-sensor 40 may also measure, in real time, vibration (impact) of the power cable 10.

Accordingly, the multi-sensor 40 may include a current sensing module, a temperature sensing module, a vibration sensing module, and the like.

The multi-sensor 40 may be mounted to each power cable 10 in the above-ground switchgear 100, and may measure the current of the corresponding power cable 10, the temperature (e.g., heat generation temperature) of the corresponding cable connector 20, and vibration (impact) applied to the power cable 10. Here, the vibration applied to the power cable 10 may be caused by an external impact applied to the above-ground switchgear 100.

In FIG. 2, the communication board 50 may receive measurement data from the multi-sensor 40 in the above-ground switchgear 100 and wirelessly transmit the data to a user terminal (not shown) or the like. The communication board 50 may receive various types of measurement data from the multi-sensor 40 and transmit the received measurement data to the user terminal (not shown) through a communication module (not shown).

Here, when transmitting the received measurement data to the user terminal, the communication board 50 may also transmit identification information or unique information of the corresponding above-ground switchgear 100. For example, the identification information or unique information of the above-ground switchgear 100 may be a combination of one or more of characters, numbers, and symbols.

For instance, the communication board 50 may transmit measurement data to the user terminal (not shown) by using a low-power wide-area (LPWA) communication technology such as Bluetooth Low Energy (BLE) protocol or Wi-Fi.

Furthermore, the communication board 50 may perform communication not only using BLE or Wi-Fi, but also using Long Range (LoRa), Wireless Smart Utility Networks (Wi-SUN), optical communication, Ethernet, or a combination thereof.

As needed, the communication board 50 may also determine, in real time, whether there is an abnormality in the current or vibration of the power cable 10 (underground power line or underground cable), or an abnormality in the temperature of the cable connector 20, based on various types of measurement data and information on preset normal ranges of current, temperature, and vibration. The communication board 50 may also generate monitoring information based on the determination result and transmit the monitoring information to the user terminal. Here, the monitoring information may include, for example, numerical values for the current and vibration of the corresponding power cable 10 and the temperature of the corresponding cable connector 20, as well as information indicating whether each parameter is within a normal range or abnormal.

The user terminal described above may receive and store various types of measurement data in real time from the communication board 50 of the above-ground switchgear 100. When monitoring information is not received from the communication board 50, the user terminal may determine whether the current of the power cable 10 is normal (or abnormal), the temperature of the cable connector 20 is normal (or abnormal), and the vibration is normal (or abnormal) based on the various types of stored measurement data, and may output the determination result as monitoring information on a display. For example, the user terminal may be a computing device having a processing function, and may be a mobile device or a fixed device. For instance, the user terminal may refer to a computer, a smartphone, a laptop computer, a tablet computer, a wearable device, or a tablet, but embodiments of the present disclosure are not limited thereto.

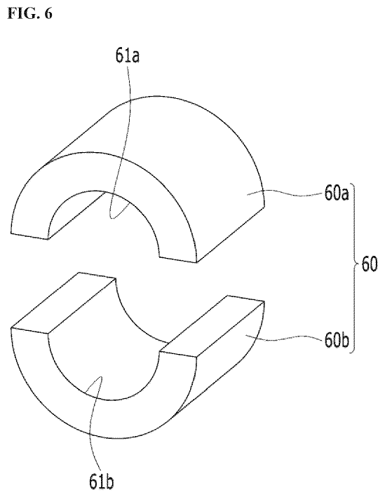

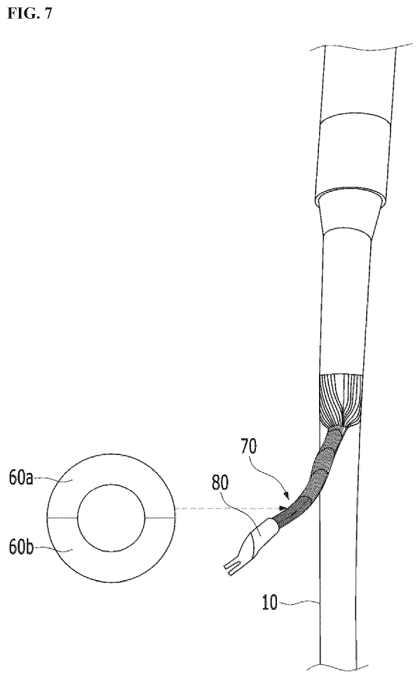

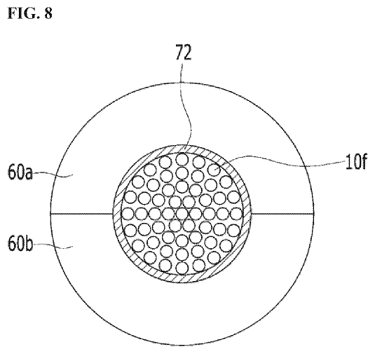

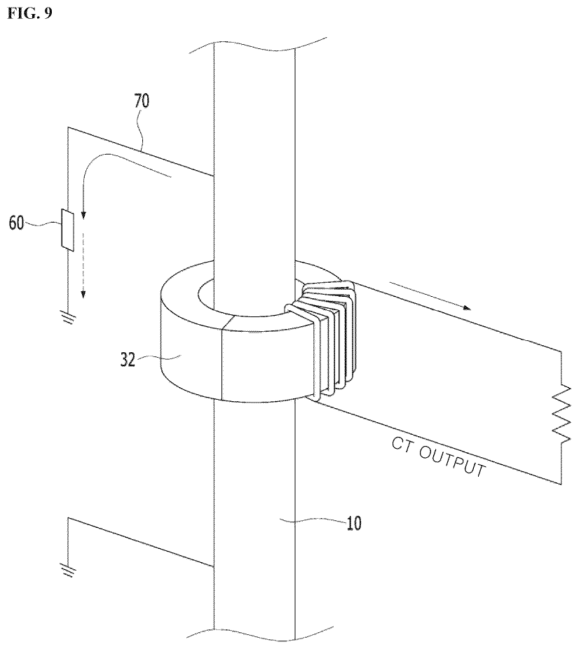

FIG. 6 is an exploded perspective view illustrating the neutral wire current suppression component according to an embodiment of the present disclosure. FIG. 7 is an enlarged view for explaining an installation position of the neutral wire current suppression component. FIG. 8 is a cross-sectional view illustrating the neutral wire current suppression component installed on a neutral wire. FIG. 9 is a diagram for explaining the output efficiency of the power induction device resulting from the neutral wire current suppression component.

The above-ground switchgear 100 according to an embodiment of the present disclosure further includes a neutral wire current suppression component 60.

The neutral wire current suppression component 60 may be installed on a grounded side of the neutral wires (more specifically, on the grounded neutral wire bundle 70).

For example, in an AC circuit, reactance (i.e., inductive reactance) is generated by a coil, and such reactance (i.e., inductive reactance) impedes the flow of current. In the same manner as the reactance (i.e., inductive reactance) of the coil in the AC circuit impedes current, the neutral current suppression component 60 is installed on the grounded neutral wire bundle 70 so as to suppress the flow of current induced through the neutral wires.

The neutral wire current suppression component 60 may be formed in a cutting core structure in which a ring-shaped core is cut, in order to maintain the characteristics of the product, eliminate the inconvenience in operating the above-ground switchgear due to line work, and ensure ease of on-site installation.

Accordingly, the neutral wire current suppression component 60 may include an upper core 60a and a lower core 60b, as illustrated in FIG. 6.

For example, the upper core 60a and the lower core 60b may be formed of cores made of a metal material, such as an iron-based material.

The upper core 60a may be curved in a semicircular shape to form a semi-cylindrical shape, and may include a receiving recess 61a. Opposite ends of the upper core 60a may extend downward and be spaced apart from each other. The upper core 60a may be an example of a first core described in the claims of the present disclosure.

The lower core 60b may be disposed below the upper core 60a, may be curved in a semicircular shape to form a semi-cylindrical shape, and may include a receiving recess 61b. Opposite ends of the lower core 60b may extend upward and be disposed to face the respective opposite ends of the upper core 60a. The lower core 60b may be an example of a second core described in the claims of the present disclosure.

That is, the neutral wire current suppression component 60 may be, for example, a donut-shaped iron-based core that is cut in half, so as to be separable into the upper core 60a and the lower core 60b.

Referring to FIG. 7, a grounding terminal 80 is provided on an end of the neutral wire bundle 70 of the power cable 10. The grounding terminal 80 may be connected to the enclosure of the above-ground switchgear 100 and grounded. The neutral wire current suppression component 60 may be installed on the grounded neutral line bundle 70. That is, the neutral wire current suppression component 60 may be installed on the grounded neutral wire bundle 70 of the power cable 10 on which the power induction device 30 is installed.

In other words, the neutral wire current suppression component 60 is installed to enclose the neutral wire bundle 70 such that the neutral wire bundle 70 is received in the receiving recesses 61a and 61b of the upper core 60a and the lower core 60b. Accordingly, as illustrated in FIG. 8, the neutral wires 10f of the neutral wire bundle 70 may be received in the receiving recesses 61a and 61b of the upper core 60a and the lower core 60b. That is, the neutral wire bundle 70 is covered with an insulator 72, and the neutral wire current suppression component 60 may be installed to enclose the periphery of the neutral wire bundle 70 that is covered with the insulator 72.

In FIG. 8, the outer surface of the neutral wire bundle 70 is illustrated as being in close contact with the receiving recesses 61a and 61b of the upper core 60a and the lower core 60b. However, as needed, the upper core 60a and the lower core 60b may be formed such that the outer surface of the neutral wire bundle 70 is in close contact with the receiving recess of one of the upper core 60a and the lower core 60b and is spaced apart from the receiving recess of a remaining one. Here, the close contact may refer to a press-fit state in which the neutral wire bundle 70 is tightly fitted into the receiving recesses 61a and 61b of the upper core 60a and the lower core 60b. The reason for bringing the neutral wire bundle 70 into close (press-fit) contact with the receiving recesses of the upper core 60a and the lower core 60b is to ensure that the neutral wire current suppression component 60 remains in place without displacement.

The neutral wire current suppression component 60 may also be understood as a bead that can be implemented in various forms.

The following describes the necessity of the neutral wire current suppression component 60 described above.

First, a conventional case in which the neutral wire current suppression component 60 is not installed on the neutral wire bundle 70 will be described.

In the case where the neutral wire current suppression component 60 is not installed on the neutral wire bundle 70 as shown in FIG. 9, a ground loop, which passes through the inside of the core 32 of the power induction device in addition to an output line of the core 32, is formed when power is induced from the power cable 10 using the power induction device 30 (e.g., a power CT). That is, in FIG. 9, as the neutral wire bundle 70 is grounded, a separate ground loop passing through the inside of the core 32 of the power induction device is formed due to the grounding. Accordingly, a portion of the magnetic flux also escapes through the ground loop, thereby weakening the magnetic flux induced in the power induction device 30. As a result, unintended power dispersion occurs due to the ground loop passing through the inside of the core 32 of the power induction device, which leads to a reduction in the output of the power induction device 30. The foregoing can also be confirmed by the fact that the current induced on the side of the multi-sensor 40 (i.e., the multi-sensor installed on the exposed and stripped portion of the neutral wires) is measured to be significantly higher than the current induced in the power induction device 30 installed to enclose the neutral wires of the power cable 10.

As described above, in the case where the neutral wire current suppression component 60 is not installed, the current values induced on the side of the multi-sensor 40 and on the side of the power induction device 30 differ significantly due to the grounding of the neutral wire.

The case according to an embodiment of the present disclosure, in which the neutral wire current suppression component 60 is installed on the grounded neutral wire bundle 70, is described as follows.

As shown in FIG. 9, even when the neutral wire current suppression component 60 is installed on the grounded neutral wire bundle 70, a ground loop passing through the inside of the core 32 of the power induction device may still be formed. However, the neutral wire current suppression component 60 increases the impedance of the corresponding line. Accordingly, the neutral wire current suppression component 60 can suppress current flowing toward the ground through the neutral wire.

In other words, compared to the case in which the neutral wire current suppression component 60 is not present, when the neutral wire current suppression component 60 is installed on the neutral wire bundle 70, the flow of current toward the ground can be significantly suppressed.

Accordingly, current flowing to the ground through the neutral wire can be effectively suppressed through adjustment of the inductance value of the neutral wire current suppression component 60. As a result, the effective current can be increased, thereby improving the output efficiency of the power induction device 30.

A clear difference depending on the presence or absence of the neutral wire current suppression component 60 is confirmed through measured results obtained from an actual site configuration.

In the case where the neutral wire current suppression component 60 is not installed, the current induced at the portion where the multi-sensor is installed was measured to be 59.4 A, the current induced from the power cable 10 on which the power induction device 30 is mounted was measured to be 7 A, and the current induced from the grounded side of the neutral wire was measured to be 32.2 A.

In contrast, in the case where the neutral wire current suppression component 60 is installed, the current induced at the portion where the multi-sensor is installed was measured to be 54.5 A, the current induced from the power cable 10 on which the power induction device 30 is mounted was measured to be 41.6 A, and the current induced from the grounded side of the neutral wire was measured to be 17.6 A.

Based on the above measurement values, it can be seen that in the case where the neutral wire current suppression component 60 is installed on the neutral wire bundle 70, the current induced from the power cable 10 on which the power induction device 30 is mounted is significantly higher than in the case without the neutral wire current suppression component 60, and the current induced from the grounded side of the neutral wire is significantly lower than in the case without the neutral wire current suppression component 60.

The foregoing experimental results demonstrate that, in the case where the neutral wire current suppression component 60 is installed on the neutral wire bundle 70, the impedance of the corresponding line increases, thereby making it difficult for the magnetic flux to escape toward the grounded side of the neutral wire.

As described above, in embodiments of the present disclosure, the neutral wire current suppression component 60 can effectively suppress current flowing toward the grounded side of the neutral wire, thereby significantly improving the output efficiency of the power induction device 30.

The above description is merely an illustrative description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. An above-ground switchgear comprising:
a connector configured to connect, to the above-ground switchgear, an underground power line emerged above ground from underground;
an energy harvester installed on the underground power line connected to the connector; and
a neutral wire current suppression component installed on a neutral wire of the underground power line, the neutral wire being connected to ground.

2. The above-ground switchgear of claim 1, wherein the neutral wire current suppression component comprises an iron-based core.

3. The above-ground switchgear of claim 1,
wherein the neutral wire current suppression component comprises:
a first core curved in a semi-circular shape and including a first receiving recess formed therein; and
a second core curved in a semi-circular shape and including a second receiving recess formed therein,
wherein the first core and the second core are installed to face each other.

4. The above-ground switchgear of claim 1, wherein the neutral wire current suppression component is installed to enclose the neutral wire.

5. The above-ground switchgear of claim 1, wherein the neutral wire current suppression component increases an impedance of the neutral wire connected to the ground and suppresses current induced through the neutral wire.

6. The above-ground switchgear of claim 1, further comprising a multi-sensor installed on the underground power line emerged above ground, the multi-sensor being installed to be spaced apart from the energy harvester.

7. The above-ground switchgear of claim 6,
wherein the energy harvester generates power through energy harvesting using a current transformer, and
wherein the power generated by the energy harvester is supplied to the multi-sensor.

8. The above-ground switchgear of claim 1,
wherein the underground power line comprises a plurality of neutral wires, and
wherein the plurality of neutral wires are exposed by a length corresponding to a length with which a sheath of the underground power line connected to the connector is stripped from an upper end of the underground power line downward, and are bent outward, bundled, and grounded.

9. The above-ground switchgear of claim 6, wherein the multi-sensor is installed on an upper portion of the underground power line from which plurality of neutral wires are exposed and grounded, such that the plurality of neutral wires are not located in the upper portion of the underground power line.

10. The above-ground switchgear of claim 8, wherein the energy harvester is installed on a lower portion of the underground power line in which the plurality of neutral wires are present.

11. The above-ground switchgear of claim 1, further comprising a communication board.

12. The above-ground switchgear of claim 11,
wherein the energy harvester generates power through energy harvesting using a current transformer, and
wherein the power generated by the energy harvester is supplied to the communication board.

13. The above-ground switchgear of claim 1, wherein the connector is grounded.
